(19) United States
(12) Patent Application Publication
(10) Pub. No.: US 2024/0388027 A1
(43) Pub. Date: Nov. 21, 2024

(54) CONNECTOR, CONNECTOR ASSEMBLY, CONNECTING STRUCTURE, AND CONNECTING METHOD

(71) Applicant: Japan Aviation Electronics Industry, Limited, Tokyo (JP)

(72) Inventor: Kenta ASHIBU, Tokyo (JP)

(21) Appl. No.: 18/602,481

(22) Filed: Mar. 12, 2024

(30) Foreign Application Priority Data
May 18, 2023 (JP) 2023-082234

(51) Int. Cl. H01R 12/77; H05K 1/02; H05K 1/11

(52) U.S. Cl. CPC H01R 12/777; H01R 12/778; H05K 1/0283; H05K 1/118; H05K 2201/09236; H05K 2201/09263; H05K 2201/0969; H05K 2201/09754

(57) ABSTRACT

The connector includes a sheet member extending in a direction orthogonal to the fitting direction and having flexibility and insulating property, a plurality of contacts retained by the sheet member at positions distanced from each other in a predetermined direction along a surface of the sheet member, and a plurality of flexible conductors disposed on the sheet member and configured to electrically connect the plurality of contacts to the plurality of wiring portions of the mounting object, the sheet member being stretchable at least in the predetermined direction, with a portion of the sheet member situated between the plurality of contacts being elastically stretched in the predetermined direction, the connector being fitted to the counter connector, the plurality of contacts separately making contact with and being electrically connected to the plurality of counter contacts due to a shrinking force generated in the sheet member.

### BACKGROUND OF THE INVENTION

The present invention relates to a connector, particularly to a connector that is mounted on a mounting object such as a garment and is fitted to a counter connector.

The present invention also relates to a connector assembly including such a connector and a counter connector.

In addition, the present invention also relates to a connecting structure and a connecting method for connecting a plurality of contacts of a connector to a plurality of counter contacts of a counter connector.

In recent years, attention has been drawn to so-called smart clothes that can acquire user's biological data such as the heart rate and the body temperature only by being worn by the user. Such smart cloths have an electrode disposed at a measurement site, and when a wearable device serving as a measurement device is electrically connected to the electrode, biological data can be transmitted to the wearable device.

The electrode and the wearable device can be interconnected by, for instance, use of a connector connected to a wiring portion drawn from the electrode.

As a connector of this type, for example, JP 2015-135723 A discloses a connector as illustrated in FIG. 19. The connector includes a male snap button 2 attached to first cloth 1 and a female snap button 4 attached to second cloth 3. The first cloth 1 and the second cloth 3 are made from conductive cloth, while the male snap button 2 and the female snap button 4 are formed of a conductive material. When a convex portion 5 of the male snap button 2 is inserted into a concave portion 6 of the female snap button 4 and pressed with two bar-like springs 7 of the female snap button 4, the male snap button 2 and the female snap button 4 are electrically connected to each other, whereby the first cloth 1 and the second cloth 3 are electrically connected to each other via the male snap button 2 and the female snap button 4.

Electrical connection of a wearable device can be made using the snap button connector as above, and when the wearable device is detached or the garment is washed for example, the electrical connection via the snap button connector can be released by separating the male snap button 2 from the female snap button 4.

In the snap button connector of JP 2015-135723 A, however, it is necessary to form a spring structure in the female snap button 4 using the two bar-like springs 7 for electrically connecting the female snap button 4 to the male snap button 2, resulting in the increase in the height of the connector, disadvantageously.

In addition, since the entire male snap button 2 and the entire female snap button 4 each function as a single electrode, connections of a plurality of wires would require attachment of as many snap button connectors as the number of the wires to a garment, which hampers miniaturization of a wearable device.

### SUMMARY OF THE INVENTION

The present invention has been made in order to solve the conventional problems described above and aims at providing a connector capable of achieving miniaturization while the connector is mounted on a mounting object such as a garment.

The present invention also aims at providing a connector assembly including such a connector and a counter connector.

In addition, the present invention also aims at providing a connecting structure and a connecting method for connecting a plurality of contacts of a connector to a plurality of counter contacts of a counter connector.

The connector according to the present invention is a connector which is configured to be mounted on a mounting object and fitted to a counter connector along a fitting direction and which includes a plurality of contacts to be connected to a plurality of counter contacts retained by a housing of the counter connector, the mounting object having a plurality of wiring portions disposed thereon, and the housing having rigidity and insulating property, the connector comprising:
a sheet member extending in a direction orthogonal to the fitting direction and having flexibility and insulating property;
the plurality of contacts retained by the sheet member at positions distanced from each other in a predetermined direction along a surface of the sheet member; and
a plurality of flexible conductors disposed on the sheet member and configured to electrically connect the plurality of contacts to the plurality of wiring portions of the mounting object,
wherein the sheet member is stretchable at least in the predetermined direction, and
with a portion of the sheet member situated between the plurality of contacts being elastically stretched in the predetermined direction, the connector is fitted to the counter connector, and the plurality of contacts separately make contact with and are electrically connected to the plurality of counter contacts due to a shrinking force generated in the sheet member.

The connector assembly according to the present invention comprises:
the foregoing connector; and
the counter connector to which the connector is fitted.

The connecting structure according to the present invention is a connecting structure for connecting a plurality of contacts of a connector, which connector is configured to be mounted on a mounting object and fitted to a counter connector along a fitting direction, to a plurality of counter contacts retained by a housing of the counter connector, the mounting object having a plurality of wiring portions disposed thereon, and the housing having rigidity and insulating property,
wherein the connector includes a sheet member extending in a direction orthogonal to the fitting direction and having flexibility and insulating property, the plurality of contacts retained by the sheet member at positions distanced from each other in a predetermined direction along a surface of the sheet member, and a plurality of flexible conductors disposed on the sheet member and configured to electrically connect the plurality of contacts to the plurality of wiring portions of the mounting object,
the sheet member is stretchable at least in the predetermined direction, and
with a portion of the sheet member situated between the plurality of contacts being elastically stretched in the predetermined direction, the connector is fitted to the counter connector, and the plurality of contacts separately make contact with and are electrically connected to the plurality of counter contacts due to a shrinking force generated in the sheet member.

The connecting method according to the present invention is a connecting method for connecting a plurality of contacts of a connector, which connector is configured to be mounted on a mounting object and fitted to a counter connector along a fitting direction, to a plurality of counter contacts retained by a housing of the counter connector, the mounting object having a plurality of wiring portions disposed thereon, and the housing having rigidity and insulating property,
wherein the connector includes a sheet member extending in a direction orthogonal to the fitting direction and having flexibility and insulating property, the plurality of contacts retained by the sheet member at positions distanced from each other in a predetermined direction along a surface of the sheet member, and a plurality of flexible conductors disposed on the sheet member and configured to electrically connect the plurality of contacts to the plurality of wiring portions of the mounting object,
the sheet member is stretchable at least in the predetermined direction,
the connecting method comprising:
fitting the connector to the counter connector with a portion of the sheet member situated between the plurality of contacts being elastically stretched in the predetermined direction; and
making the plurality of contacts separately contact with the plurality of counter contacts due to a shrinking force generated in the sheet member to electrically connect the plurality of contacts to the plurality of counter contacts.

### BRIEF DESCRIPTION OF THE DRAWINGS

FIG. 1 is a perspective view showing a connector assembly according to Embodiment 1 mounted on a mounting object.

FIG. 2 is a plan view showing the connector assembly according to Embodiment 1.

FIG. 3 is a perspective view showing a connector used in Embodiment 1.

FIG. 4 is a perspective view showing a counter connector used in Embodiment 1.

FIG. 5 is a cross-sectional view showing a counter contact of the counter connector used in Embodiment 1.

FIG. 6 is a plan view showing the connector in Embodiment 1 fitted with the counter connector.

FIG. 7 is a cross-sectional view taken along line A-A in FIG. 2.

FIG. 8 is a perspective view showing a connector assembly according to Embodiment 2.

FIG. 9 is a perspective view showing a connector used in Embodiment 2.

FIG. 10 is a perspective view showing a connector assembly according to Embodiment 3.

FIG. 11 is a perspective view showing a connector used in Embodiment 3.

FIG. 12 is a perspective view showing a connector assembly according to Embodiment 4.

FIG. 13 is a plan view showing the connector assembly according to Embodiment 4.

FIG. 14 is a perspective view showing a connector used in Embodiment 4.

FIG. 15 is a perspective view showing a contact of the connector used in Embodiment 4.

FIG. 16 is a perspective view showing a counter connector used in Embodiment 4.

FIG. 17 is a cross-sectional view taken along line B-B in FIG. 13.

FIG. 18 is a side view showing a modification of the connector assembly according to Embodiment 4.

FIG. 19 is a cross-sectional view showing a conventional connector.

### DETAILED DESCRIPTION OF THE INVENTION

Embodiments of the present invention are described below based on the accompanying drawings.

### Embodiment 1

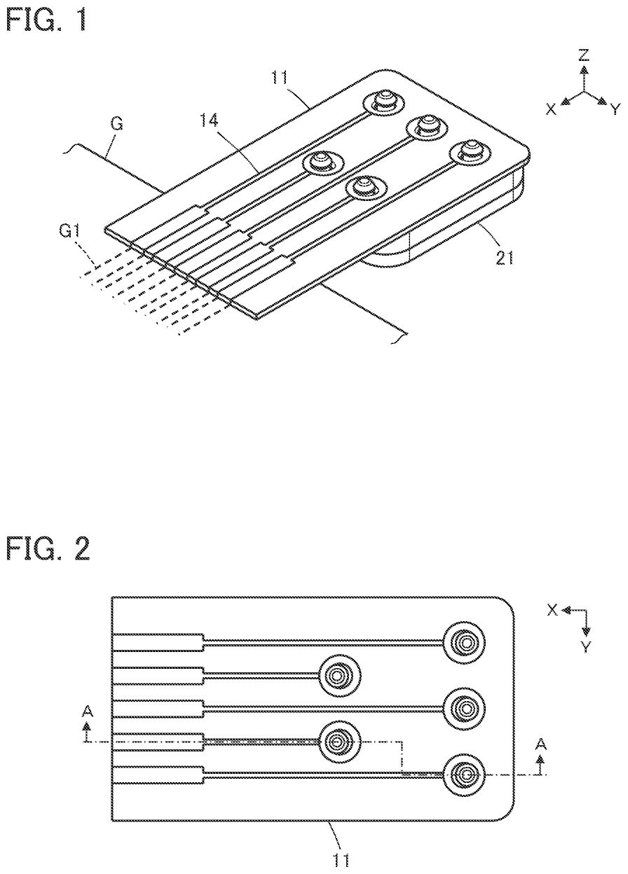

FIGS. 1 and 2 show a connector assembly according to Embodiment 1. The connector assembly includes a connector 11 and a counter connector 21 to which the connector 11 is fitted.

The connector 11 has a sheet shape and is fitted to the counter connector 21 with part of the connector 11 being superposed on the counter connector 21.

For instance, the connector 11 is mounted on a garment G, i.e., a mounting object to be thus used as a garment-side connector, while the counter connector 21 fitted to the connector 11 is used as a module-side connector.

For convenience, the connector 11 having a sheet shape is defined as extending along an XY plane, the direction from the connector 11 to the garment G is referred to as “+X direction,” and the direction from the counter connector 21 to the connector 11 and perpendicular to an XY plane is referred to as “+Z direction.” The Z direction is a fitting direction of the connector 11 and the counter connector 21.

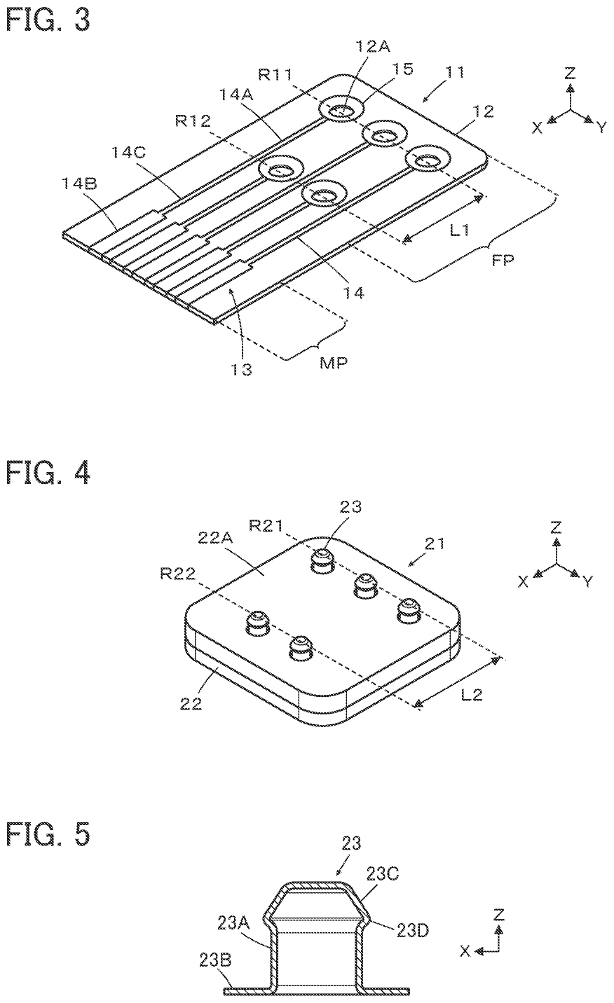

As shown in FIG. 3, the connector 11 includes an insulating sheet member 12 extending along an XY plane. The sheet member 12 includes a fitting portion FP that is arranged at a −X direction side portion of the sheet member 12 and is fitted to the counter connector 21, and a mounting portion MP that is arranged at a +X direction side portion of the sheet member 12 and is mounted on the garment G.

The sheet member 12 is made of, for example, insulating cloth, knitted fabric, or rubber material and is a flexible member that is stretchable at least in the X direction. The sheet member 12 is provided with an embroidery pattern 13 embroidered with embroidery threads.

By using a conductive thread as the embroidery thread to form the embroidery pattern 13, a plurality of flexible conductors 14 having electrical conductivity are formed.

Each flexible conductor 14 includes a linear first connection portion 14A disposed in the fitting portion FP of the sheet member 12 and extending in the X direction, a rectangular second connection portion 14B disposed in the mounting portion MP of the sheet member 12, and a joint portion 14C joining the first connection portion 14A and the second connection portion 14B to each other.

Since the flexible conductors 14 are formed of the embroidery threads, at least the first connection portion 14A extending in the X direction in each flexible conductor 14 is configured to be stretchable in the X direction.

The connector 11 includes a plurality of contacts 15 attached to the fitting portion FP of the sheet member 12 and electrically connected to the first connection portions 14A of the flexible conductors 14.

A contact 15 is a ring-shaped, specifically, a so-called donut-shaped conductive member made of, for example, metal, and is attached to the peripheral portion of a sheet-side through hole 12A formed at a portion of the sheet member 12 at which portion the first connection portion 14A of the corresponding flexible conductor 14 is disposed. As the contact 15, for example, a ring-shaped metal part, so-called “grommet,” can be used.

The contacts 15 are separately arranged in a first contact array R11 and a second contact array R12 in a so-called staggered manner, the first contact array R11 extending in the Y direction in a −X direction side portion of the fitting portion FP, and the second contact array R12 extending in the Y direction in a +X direction side portion of the fitting portion FP.

When no external force such as a tensile force acts on the sheet member 12, the center of each contact 15 arranged in the first contact array R11 is distanced from the center of each contact 15 arranged in the second contact array R12 by a distance L1 in the X direction.

As shown in FIG. 4, the counter connector 21 includes an insulating housing 22 having rigidity, and a plurality of counter contacts 23 retained by the housing 22.

The housing 22 includes a connector-opposing surface 22A of planar shape extending along an XY plane and facing in the +Z direction, and the counter contacts 23 have their respective tubular portions protruding in the +Z direction from the connector-opposing surface 22A.

The counter contacts 23 are separately arranged in a first counter contact array R21 and a second counter contact array R22 in a so-called staggered manner, the first counter contact array R21 extending in the Y direction in a −X direction side portion of the housing 22, and the second counter contact array R22 extending in the Y direction in a +X direction side portion of the housing 22.

The center of each counter contact 23 arranged in the first counter contact array R21 is distanced from the center of each counter contact 23 arranged in the second counter contact array R22 by a distance L2 in the X direction.

The distance L2 between the counter contacts 23 in the X direction in the counter connector 21 is set to have a value larger than the distance L1 between the contacts 15 in the X direction in the connector 11 by a difference dL.

The intervals of the centers of the counter contacts 23 in the Y direction in the counter connector 21 are set to be equal to the intervals of the centers of the contacts 15 in the Y direction in the connector 11.

As shown in FIG. 5, each counter contact 23 has a tubular portion 23A of cylindrical shape extending in the +Z direction, and a flange 23B extending from the −Z directional end of the tubular portion 23A along an XY plane. The tubular portion 23A is provided at the +Z directional end thereof with an inviting portion 23C of conical shape tapering toward the +Z direction, and the inviting portion 23C is provided at the −Z directional end thereof with an overhanging portion 23D overhanging in a radial direction relative to the tubular portion 23A. The outer diameter of the overhanging portion 23D is set to be smaller than the inner diameter of the ring-shaped contact 15 in the connector 11, and the tubular portion 23A and the inviting portion 23C are formed such that these portions can be inserted in the ring-shaped contact 15 of the connector 11.

Meanwhile, since the distance L2 in the X direction from the counter contacts 23 arranged in the first counter contact array R21 to the counter contacts 23 arranged in the second counter contact array R22 in the counter connector 21 is longer than the distance L1 in the X direction from the contacts 15 arranged in the first contact array R11 to the contacts 15 arranged in the second contact arrays R12 in the connector 11 by the difference dL, it is not possible to insert all of the counter contacts 23 in the corresponding contacts 15 by merely disposing the fitting portion FP of the connector 11 straight above the counter connector 21.

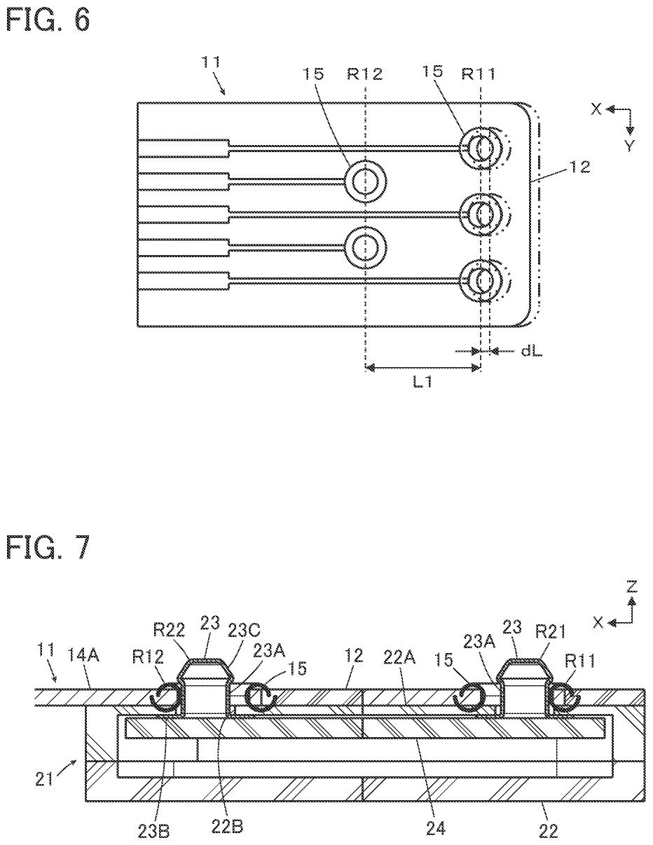

Hence, for fitting the connector 11 to the counter connector 21, first, as indicated by the two-dot chain line in FIG. 6, a tensile force in the X direction is applied to the stretchable sheet member 12 of the connector 11, whereby the distance in the X direction from the centers of the contacts 15 arranged in the first contact array R11 to the centers of the contacts 15 arranged in the second contact array R12 is stretched by the difference dL.

In other words, until the distance in the X direction from the contacts 15 arranged in the first contact array R11 to the contacts 15 arranged in the second contact array R12 of the connector 11 becomes equal to the distance L2 (L1+dL) in the X direction from counter contacts 23 arranged in the first counter contact array R21 to the counter contacts 23 arranged in the second counter contact array R22 of the counter connector 21, a portion of the sheet member 12 situated between the contacts 15 in the connector 11 is stretched in the X direction.

As a result, the positional interrelationship of the contacts 15 of the connector 11 becomes equal to that of the counter contacts 23 of the counter connector 21 both in the X direction and the Y direction.

In this state, the fitting portion FP of the sheet member 12 of the connector 11 is moved toward the connector-opposing surface 22A of the housing 22 of the counter connector 21 in the −Z direction from the +Z direction, whereby the connector 11 is fitted to the counter connector 21, and the counter contacts 23 of the counter connector 21 are separately inserted in the corresponding ring-shaped contacts 15 of the connector 11.

Thereafter, the tensile force in the X direction having been applied to the sheet member 12 of the connector 11 is released, whereby the portion of the sheet member 12 situated between the contacts 15 shrinks in the X direction, and the distance from the centers of the contacts 15 in the first contact array R11 to the centers of the contacts 15 in the second contact array R12 is shortened.

The connector 11 and the counter connector 21 that are fitted to each other in this manner are shown in FIG. 7. A module substrate 24 is included inside the housing 22 of the counter connector 21, and the flanges 23B of the counter contacts 23 are mounted on the module substrate 24. While the tubular portions 23A and the inviting portions 23C of the respective counter contacts 23 protrude in the +Z direction from the connector-opposing surface 22A via through holes 22B of the housing 22 and are inserted in the corresponding ring-shaped contacts 15 of the connector 11, the tensile force having been applied to the sheet member 12 of the connector 11 is released, resulting in generation of a shrinking force in the sheet member 12.

Accordingly, the inner peripheral portions on the −X direction side of the contacts 15 in the first contact array R11 of the connector 11 make contact with the outer peripheral portions on the −X direction side of the counter contacts 23 in the first counter contact array R21 of the counter connector 21 with predetermined contact pressure, and the inner peripheral portions on the +X direction side of the contacts 15 in the second contact array R12 of the connector 11 make contact with the outer peripheral portions on the +X direction side of the counter contacts 23 in the second counter contact array R22 of the counter connector 21 with predetermined contact pressure.

As a result, the contacts 15 of the connector 11 are separately and electrically connected to the counter contacts 23 of the counter connector 21.

As shown in FIG. 1, the bottom surface of the garment G, i.e., a mounting object, is provided with a plurality of conductive wiring portions G1 corresponding to the plurality of flexible conductors 14 of the connector 11, and when the second connection portions 14B disposed in the mounting portion MP of the sheet member 12 of the connector 11 shown in FIG. 3 are each sewn to an end of the corresponding wiring portion G1 of the garment G using, for example, a conductive sewing thread, the flexible conductors 14 are separately and electrically connected to the wiring portions G1 of the garment G.

As a result, the counter contacts 23 of the counter connector 21 can be separately and electrically connected to the wiring portions G1 of the garment G via the contacts 15 and the flexible conductors 14 of the connector 11.

The other ends of the wiring portions G1 each extend along the bottom surface of the garment G up to an electrode (not shown) attached to the garment G.

Hence, when a predetermined electronic circuit is mounted on the module substrate 24 included in the counter connector 21, biological data acquired through the electrode can be measured by the electronic circuit or transmitted to a remote measurement device from the electronic circuit.

In the connector 11 in Embodiment 1, the plurality of flexible conductors 14 and the plurality of ring-shaped contacts 15 are disposed in the flexible and stretchable sheet member 12 that is made of insulating cloth or knitted fabric, the connector 11 is fitted to the counter connector 21 while a portion of the sheet member 12 situated between the contacts 15 is elastically stretched, and the contacts 15 separately make contact with the counter contacts 23 due to a shrinking force generated in the sheet member 12 to be thereby electrically connected to the counter contacts 23; therefore, the connector 11 can achieve miniaturization, particularly reduction in the thickness.

In addition, by mounting the connector 11 to an outside of the garment G, it is possible to suppress deterioration in comfortableness in wearing the garment G even when the connector 11 is fitted to the counter connector 21.

Note that each counter contact 23 has the inviting portion 23C of conical shape tapering toward the +Z direction. Hence, for fitting the connector 11 to the counter connector 21, for instance, in a state where the counter contacts 23 in the second counter contact array R22 of the counter connector 21 are inserted in the through holes of the contacts 15 in the second contact array R12 of the connector 11, the −X directional end of the sheet member 12 is pulled in the −X direction with respect to the counter connector 21, and the contacts 15 in the first contact array R11 are pulled down in the −Z direction when the through holes of the contacts 15 in the first contact array R11 of the connector 11 are superposed on the +Z directional ends, on the +Z direction side, of the inviting portions 23C of the counter contacts 23 in the first counter contact array R21 of the counter connector 21, whereby the counter contacts 23 of the counter connector 21 can be separately inserted in the contacts 15 of the connector 11.

### Embodiment 2

In Embodiment 1 described above, the contacts 15 attached to the sheet member 12 of the connector 11 are each composed of a so-called donut-shaped conductive member, but the invention is not limited thereto.

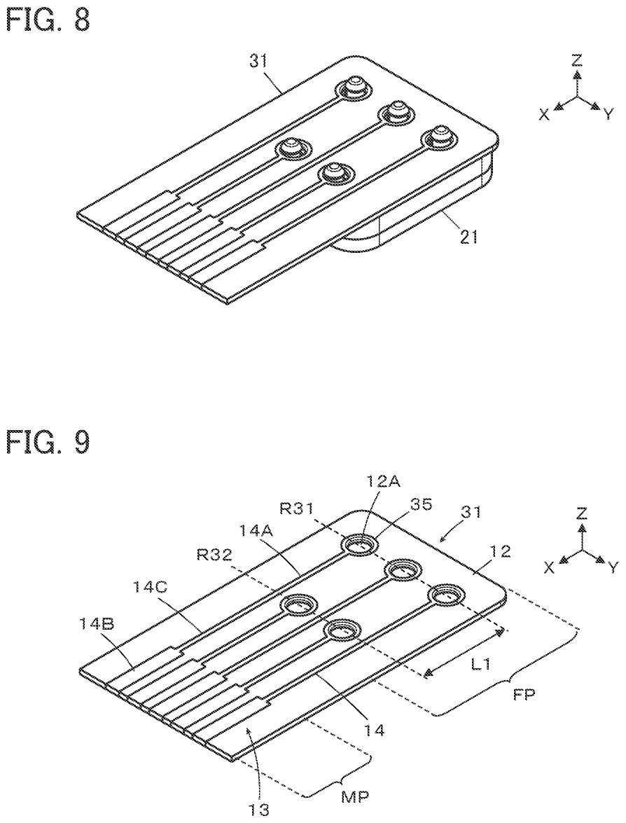

FIG. 8 shows a connector assembly according to Embodiment 2. The connector assembly includes a connector 31 and the counter connector 21 to which the connector 31 is fitted. The counter connector 21 herein is the same as that used in Embodiment 1.

The configuration of the connector 31 is shown in FIG. 9. The connector 31 is configured such that in the connector 11 in Embodiment 1, in place of the contacts 15, a plurality of contacts 35 are attached to the fitting portion FP of the sheet member 12; the connector 31 is otherwise configured similarly to the connector 11. That is, the flexible conductors 14 are formed on the sheet member 12, and the contacts 35 are disposed in the fitting portion FP of the sheet member 12.

The contacts 35 are separately arranged in a first contact array R31 and a second contact array R32, the first contact array R31 extending in the Y direction in a −X direction side portion of the fitting portion FP, and the second contact array R32 extending in the Y direction in a +X direction side portion of the fitting portion FP, and when no external force such as a tensile force acts on the sheet member 12, the center of each contact 35 arranged in the first contact array R31 is distanced from the center of each contact 35 arranged in the second contact array R32 by the distance L1 in the X direction, as with Embodiment 1.

Each contact 35 includes a ring-shaped conductor portion formed along the inner peripheral portion of the sheet-side through hole 12A formed in the sheet member 12, and is electrically connected to the first connection portion 14A of the corresponding flexible conductor 14.

Even with the contacts 35 as above, realized is the connector 31 which is fitted to the counter connector 21 while a portion of the sheet member 12 situated between the contacts 35 is elastically stretched, and in which the contacts 35 separately make contact with and are electrically connected to the counter contacts 23 due to a shrinking force generated in the sheet member 12, similarly to Embodiment 1. As with the connector 11 according to Embodiment 1, the connector 31 can achieve miniaturization, particularly reduction in the thickness.

### Embodiment 3

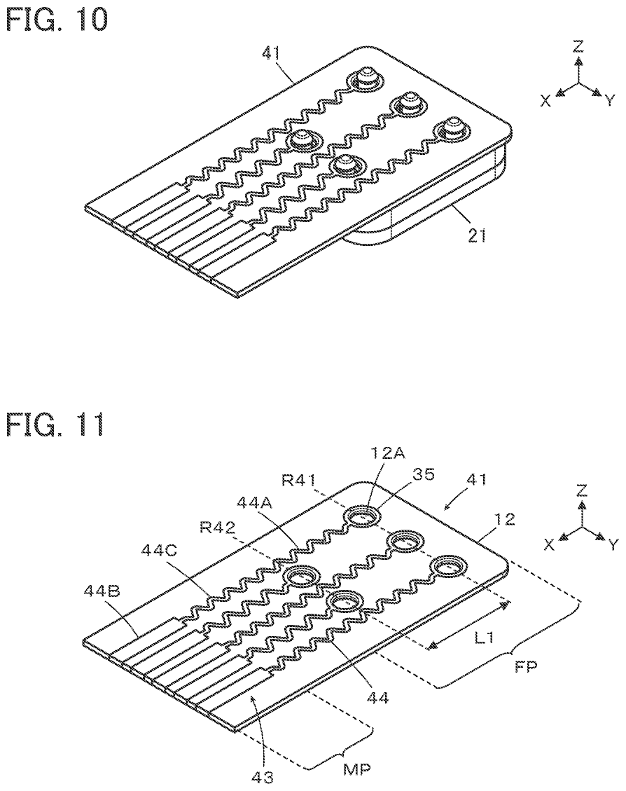

FIG. 10 shows a connector assembly according to Embodiment 3. The connector assembly includes a connector 41 and the counter connector 21 to which the connector 41 is fitted. The counter connector 21 herein is the same as that used in Embodiments 1 and 2.

The configuration of the connector 41 is shown in FIG. 11. The connector 41 is configured such that in the connector 31 in Embodiment 2, in place of the flexible conductors 14, a plurality of flexible conductors 44 are formed on the sheet member 12; the connector 41 is otherwise configured similarly to the connector 31. In other words, the sheet member 12 is provided with an embroidery pattern 43 embroidered with embroidery threads, and the flexible conductors 44 having electrical conductivity are formed of the embroidery pattern 43.

Each flexible conductor 44 includes a first connection portion 44A disposed in the fitting portion FP of the sheet member 12 and extending in the X direction, a rectangular second connection portion 44B disposed in the mounting portion MP of the sheet member 12, and a joint portion 44C joining the first connection portion 44A and the second connection portion 44B to each other. The first connection portion 44A and the joint portion 44C extend in a zigzag manner along the X direction, that is, extend in the X direction while repeatedly bending in the Y direction.

The contacts 35 are separately arranged in a first contact array R41 and a second contact array R42, the first contact array R41 extending in the Y direction in a −X direction side portion of the fitting portion FP, and the second contact array R42 extending in the Y direction in a +X direction side portion of the fitting portion FP, and when no external force such as a tensile force acts on the sheet member 12, the center of each contact 35 arranged in the first contact array R41 is distanced from the center of each contact 35 arranged in the second contact array R42 by the distance L1 in the X direction, as with Embodiments 1 and 2.

Since the first connection portion 44A and the joint portion 44C of each flexible conductor 44 extend in the X direction in a zigzag manner, when the sheet member 12 is stretched in the X direction by a tensile force applied thereto, the first connection portion 44A and the joint portion 44C are deformed in an XY plane such that the bending width in the Y direction of the zigzag shape having repeated bends is narrowed and thus can be elongated in the X direction together with the sheet member 12.

Accordingly, even when the flexible conductors 44 formed of conductive threads do not have sufficient stretchability, it is possible to realize the connector 41 which is fitted to the counter connector 21 while the sheet member 12 is elastically stretched in the X direction, and in which the contacts 35 separately make contact with and are electrically connected to the counter contacts 23 due to a shrinking force generated in the sheet member 12, similarly to Embodiments 1 and 2. Thus, the connector 41 can achieve miniaturization, particularly reduction in the thickness.

### Embodiment 4

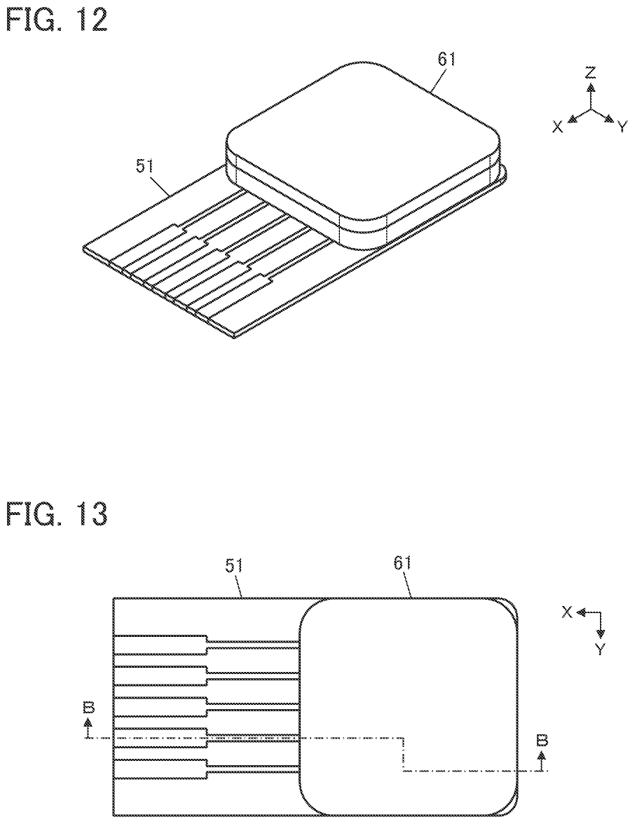

FIGS. 12 and 13 show a connector assembly according to Embodiment 4. The connector assembly includes a connector 51 and a counter connector 61 to which the connector 51 is fitted.

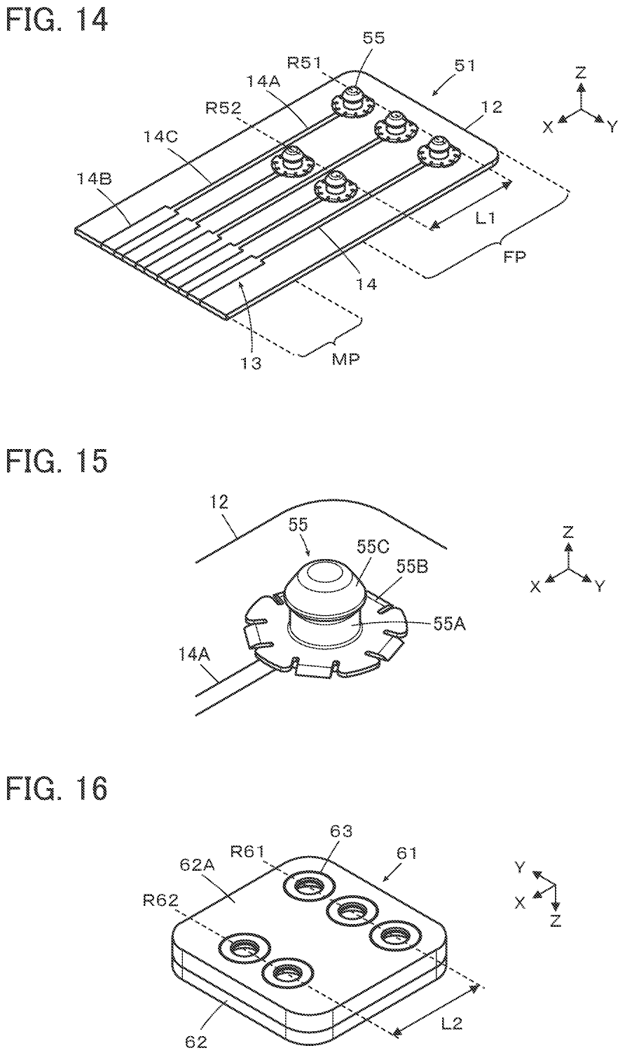

The configuration of the connector 51 is shown in FIG. 14. The connector 51 is configured such that in the connector 11 in Embodiment 1, in place of the contacts 15, a plurality of contacts 55 each projecting in the +Z direction are attached to the fitting portion FP of the sheet member 12; the connector 51 is otherwise configured similarly to the connector 11. That is, the flexible conductors 14 are formed on the sheet member 12, and the contacts 55 are disposed in the fitting portion FP of the sheet member 12.

The contacts 55 are separately arranged in a first contact array R51 and a second contact array R52, the first contact array R51 extending in the Y direction in a −X direction side portion of the fitting portion FP, and the second contact array R52 extending in the Y direction in a +X direction side portion of the fitting portion FP, and when no external force such as a tensile force acts on the sheet member 12, the center of each contact 55 arranged in the first contact array R51 is distanced from the center of each contact 55 arranged in the second contact array R52 by the distance L1 in the X direction, as with Embodiment 1.

As shown in FIG. 15, each contact 55 has a tubular portion 55A of cylindrical shape extending in the +Z direction, and a flange 55B extending from the −Z directional end of the tubular portion 55A along an XY plane. Part of the flange 55B penetrates the sheet member 12 and is bent toward the −Z direction side of the sheet member 12, whereby the contact 55 is retained by the sheet member 12 and is electrically connected to the corresponding first connection portion 14A.

In addition, the tubular portion 55A is provided at the +Z directional end thereof with an inviting portion 55C of conical shape tapering toward the +Z direction.

As shown in FIG. 16, the counter connector 61 includes an insulating housing 62 having rigidity, and a plurality of counter contacts 63 retained by the housing 62.

The housing 62 includes a connector-opposing surface 62A of planar shape extending along an XY plane and facing in the −Z direction, and the counter contacts 63 are retained by the housing 62 so as to be exposed in the −Z direction from the connector-opposing surface 62A.

The counter contacts 63 are separately arranged in a first counter contact array R61 and a second counter contact array R62, the first counter contact array R61 extending in the Y direction in a −X direction side portion of the housing 62, and the second counter contact array R62 extending in the Y direction in a +X direction side portion of the housing 62.

The center of each counter contact 63 arranged in the first counter contact array R61 is distanced from the center of each counter contact 63 arranged in the second counter contact array R62 by a distance L2 in the X direction.

The distance L2 between the counter contacts 63 in the X direction in the counter connector 61 is set to have a value larger than the distance L1 between the contacts 55 in the X direction in the connector 51.

Each counter contact 63 is a flat plate- and ring-shaped conductive member made of, for example, metal and is provided at the center thereof with a through hole in which the tubular portion 55A and the inviting portion 55C of the contact 55 of the connector 51 can be inserted.

For fitting the connector 51 to the counter connector 61, as with Embodiment 1, first, a tensile force in the X direction is applied to the stretchable sheet member 12 of the connector 51, whereby a portion of the sheet member 12 situated between the contacts 55 in the first contact array R51 and the contacts 55 in the second contact array R52 is stretched in the X direction.

In this state, the fitting portion FP of the sheet member 12 of the connector 51 is moved from the −Z direction toward the connector-opposing surface 62A of the housing 62 of the counter connector 61 relatively in the +Z direction, whereby the connector 51 is fitted to the counter connector 61, and the tubular portions 55A and the inviting portions 55C of the contacts 55 of the connector 51 are separately inserted in the corresponding ring-shaped counter contacts 63 of the counter connector 61.

Thereafter, the tensile force in the X direction having been applied to the sheet member 12 of the connector 51 is released, whereby the portion of the sheet member 12 situated between the contacts 55 shrinks in the X direction, and the distance from the centers of the contacts 55 in the first contact array R51 to the centers of the contacts 55 in the second contact array R52 is shortened.

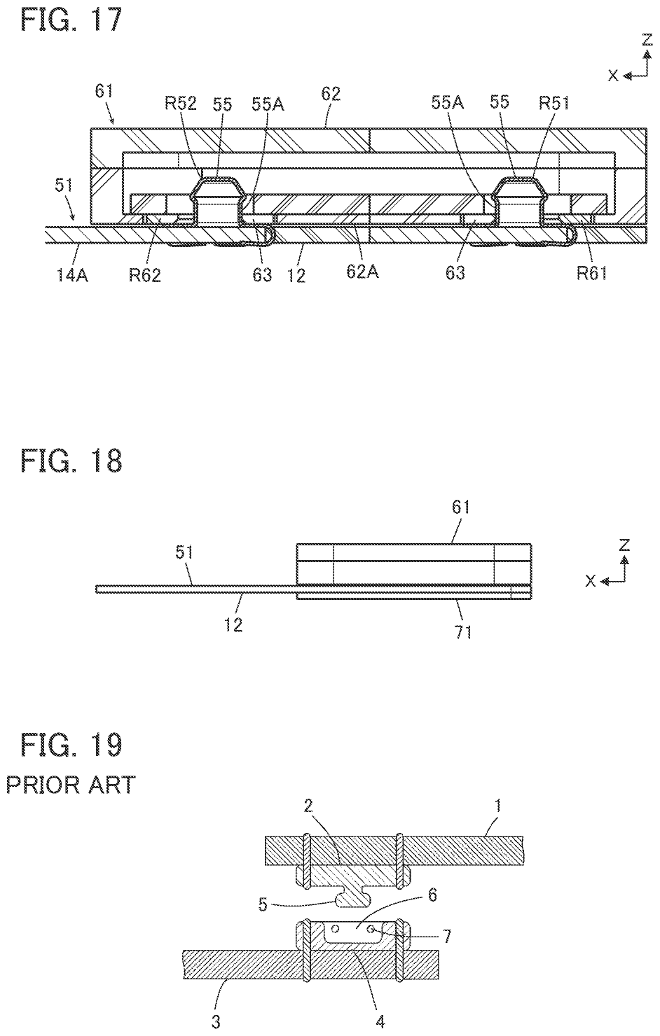

Accordingly, as shown in FIG. 17, the outer peripheral portions on the +X direction side of the contacts 55 in the first contact array R51 of the connector 51 make contact with the inner peripheral portions on the +X direction side of the counter contacts 63 in the first counter contact array R61 of the counter connector 61 with predetermined contact pressure, and the outer peripheral portions on the −X direction side of the contacts 55 in the second contact array R52 of the connector 51 make contact with the inner peripheral portions on the −X direction side of the counter contacts 63 in the second counter contact array R62 of the counter connector 61 with predetermined contact pressure.

As a result, the contacts 55 of the connector 51 are separately and electrically connected to the counter contacts 63 of the counter connector 61.

As described above, even when the contacts 55 projecting in the +Z direction are attached to the flexible and stretchable sheet member 12 of the connector 51, while the ring-shaped counter contacts 63 are disposed in the housing 62 having rigidity of the counter connector 61, it is possible to realize the connector 51 that is miniaturized, particularly thinned.

Meanwhile, as shown in FIG. 18, an auxiliary member 71 can be attached to the opposite surface from the surface facing the counter connector 61, i.e., the −Z directional surface, of the sheet member 12 of the connector 51.

The auxiliary member 71 is made of, for example, a rubber material or a like material and is stretchable at least in the X direction, similarly to the sheet member 12. The auxiliary member 71 is attached at a position corresponding to the fitting portion FP of the sheet member 12.

With the auxiliary member 71 as above being attached to the sheet member 12, even when the sheet member 12 is not sufficiently stretchable, the stretchability of the auxiliary member 71 generates a shrinking force to thereby enable electrical connection between the contacts 55 of the connector 51 and the counter contacts 63 of the counter connector 61 with high reliability.

A similar auxiliary member can be attached to the sheet member 12 not only in the connector 51 of Embodiment 4 but also in the connector 11, 31, 41 of Embodiments 1 to 3. It should be noted that in a case where an auxiliary member is attached to the sheet member 12 in the connector 11, 31, 41 of Embodiments 1 to 3, it is necessary to dispose the auxiliary member on the +Z directional surface of the sheet member 12 and form through holes in the auxiliary member such that tubular portions 23A and the inviting portions 23C of the counter contacts 23 of the counter connector 21 are passed through the through holes.

The number of the contacts 15, 35, 55 of the connector 11, 31, 41, 51 and the number of the counter contacts 22, 63 of the counter connector 21, 61 in Embodiments 1 to 4 described above are not particularly limited, and it suffices if two or more contacts of a connector are configured to be connected to two or more counter contacts of a counter connector.

In addition, while the connector 11, 31, 41, 51 is mounted on the garment G as a mounting object in Embodiments 1 to 4 described above, the mounting object is not limited to the garment G, and the connector can be mounted on various types of mounting objects.

What is claimed is:

1. A connector which is configured to be mounted on a mounting object and fitted to a counter connector along a fitting direction and which includes a plurality of contacts to be connected to a plurality of counter contacts retained by a housing of the counter connector, the mounting object having a plurality of wiring portions disposed thereon, and the housing having rigidity and insulating property, the connector comprising:
a sheet member extending in a direction orthogonal to the fitting direction and having flexibility and insulating property;
the plurality of contacts retained by the sheet member at positions distanced from each other in a predetermined direction along a surface of the sheet member; and
a plurality of flexible conductors disposed on the sheet member and configured to electrically connect the plurality of contacts to the plurality of wiring portions of the mounting object,
wherein the sheet member is stretchable at least in the predetermined direction, and
with a portion of the sheet member situated between the plurality of contacts being elastically stretched in the predetermined direction, the connector is fitted to the counter connector, and the plurality of contacts separately make contact with and are electrically connected to the plurality of counter contacts due to a shrinking force generated in the sheet member.

2. The connector according to claim 1,
wherein the plurality of contacts are separately arranged in two contact arrays, the two contact arrays being distanced from each other in the predetermined direction and each extending in a direction orthogonal to the predetermined direction,
the plurality of counter contacts are separately arranged in two counter contact arrays, the two counter contact arrays being distanced from each other in the predetermined direction and each extending in a direction orthogonal to the predetermined direction, and
when no external force acts on the sheet member, a distance along the predetermined direction between the two counter contact arrays is longer than a distance along the predetermined direction between the two contact arrays.

3. The connector according to claim 1,
wherein the sheet member includes a fitting portion that is superposed on the counter connector when the connector is fitted to the counter connector, and a mounting portion that is configured to be mounted on the mounting object,
the plurality of contacts are retained in the fitting portion of the sheet member, and
the plurality of flexible conductors include a plurality of first connection portions disposed in the fitting portion and electrically connected to the plurality of contacts, a plurality of second connection portions disposed in the mounting portion and configured to be electrically connected to the plurality of wiring portions of the mounting object, and a plurality of joint portions joining the plurality of first connection portions to the plurality of second connection portions.

4. The connector according to claim 1,
wherein the sheet member is formed of cloth, knitted fabric, or a rubber material, and
the plurality of flexible conductors are each formed of a conductive thread embroidered on or woven into the sheet member.

5. The connector according to claim 1,
wherein the plurality of counter contacts each include a tubular portion of cylindrical shape projecting in the fitting direction from the housing,
the plurality of contacts are each formed of a conductive member of ring shape in which a corresponding one of the counter contacts is inserted, and
an inner peripheral portion of the conductive member makes contact with an outer peripheral portion of the tubular portion due to the shrinking force generated in the sheet member.

6. The connector according to claim 1,
wherein the plurality of contacts each include a tubular portion of cylindrical shape projecting in the fitting direction from the sheet member,
the plurality of counter contacts are each formed of a conductive member of ring shape in which a corresponding one of the contacts is inserted, and
an outer peripheral portion of the tubular portion makes contact with an inner peripheral portion of the conductive member due to the shrinking force generated in the sheet member.

7. The connector according to claim 3, wherein the plurality of flexible conductors separately extend from the first connection portions toward the second connection portions in a zigzag manner.

8. The connector according to claim 3, further comprising an auxiliary member that is stretchable and is attached to a surface of the sheet member opposite from a surface facing the counter connector and at a position corresponding to the fitting portion.

9. The connector according to claim 1, wherein the connector is configured to be mounted on a garment as the mounting object.

10. A connector assembly comprising:
the connector according to claim 1; and
the counter connector to which the connector is fitted.

11. A connecting structure for connecting a plurality of contacts of a connector, which connector is configured to be mounted on a mounting object and fitted to a counter connector along a fitting direction, to a plurality of counter contacts retained by a housing of the counter connector, the mounting object having a plurality of wiring portions disposed thereon, and the housing having rigidity and insulating property,
wherein the connector includes a sheet member extending in a direction orthogonal to the fitting direction and having flexibility and insulating property, the plurality of contacts retained by the sheet member at positions distanced from each other in a predetermined direction along a surface of the sheet member, and a plurality of flexible conductors disposed on the sheet member and configured to electrically connect the plurality of contacts to the plurality of wiring portions of the mounting object,
the sheet member is stretchable at least in the predetermined direction, and
with a portion of the sheet member situated between the plurality of contacts being elastically stretched in the predetermined direction, the connector is fitted to the counter connector, and the plurality of contacts separately make contact with and are electrically connected to the plurality of counter contacts due to a shrinking force generated in the sheet member.

12. A connecting method for connecting a plurality of contacts of a connector, which connector is configured to be mounted on a mounting object and fitted to a counter connector along a fitting direction, to a plurality of counter contacts retained by a housing of the counter connector, the mounting object having a plurality of wiring portions disposed thereon, and the housing having rigidity and insulating property,
wherein the connector includes a sheet member extending in a direction orthogonal to the fitting direction and having flexibility and insulating property, the plurality of contacts retained by the sheet member at positions distanced from each other in a predetermined direction along a surface of the sheet member, and a plurality of flexible conductors disposed on the sheet member and configured to electrically connect the plurality of contacts to the plurality of wiring portions of the mounting object,
the sheet member is stretchable at least in the predetermined direction,
the connecting method comprising:
fitting the connector to the counter connector with a portion of the sheet member situated between the plurality of contacts being elastically stretched in the predetermined direction; and
making the plurality of contacts separately contact with the plurality of counter contacts due to a shrinking force generated in the sheet member to electrically connect the plurality of contacts to the plurality of counter contacts.
